(19) United States
(12) Patent Application Publication
(10) Pub. No.: US 2023/0378179 A1
(43) Pub. Date: Nov. 23, 2023

(54) Semiconductor Device and Method of Manufacturing the Same

(71) Applicant: Taiwan Semiconductor Manufacturing Co.,Ltd., Hsinchu (TW)

(72) Inventors: Bo-Feng Young, Taipei (TW); Sai-Hooi Yeong, Zhubei City (TW); Chi On Chui, Hsinchu (TW)

(21) Appl. No.: 17/815,078

(22) Filed: Jul. 26, 2022

Related U.S. Application Data
(60) Provisional application No. 63/364,831, filed on May 17, 2022.

(51) Int. Cl. H01L 27/092; H01L 29/786; H01L 21/02; H01L 21/8258; H01L 29/66

(52) U.S. Cl. CPC H01L 27/0922; H01L 27/0924; H01L 29/78618; H01L 29/78696; H01L 29/7869; H01L 21/02565; H01L 21/8258; H01L 29/66969

(57) ABSTRACT

A method includes forming a thin-film omega transistor, which includes forming a gate fin over a dielectric layer, forming a gate dielectric on sidewalls and a top surface of the gate fin, and depositing an oxide semiconductor layer over the gate dielectric. The gate fin, the gate dielectric, and the oxide semiconductor layer collectively form a fin structure. A source region is formed to contact first sidewalls and a first top surface of a first portion of the oxide semiconductor layer. A drain region is formed to contact second sidewalls and a second top surface of a second portion of the oxide semiconductor layer.

### PRIORITY CLAIM AND CROSS-REFERENCE

This application claims the benefit of the following provisionally filed U.S. patent application: Application No. 63/364,831, filed on May 17, 2022, and entitled “Metal Oxide Thin Film Omega Transistor (TFOT) for CFET CMOS Application Integrated in BEOL,” which application is hereby incorporated herein by reference.

### BACKGROUND

With the increasingly more demanding requirement for more functionality and higher speed in integrated circuits, integrated circuit devices are increasingly down-scaled. This introduces the need of having new devices and more flexibility in the design and the manufacturing of integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a thin-film omega transistor in accordance with some embodiments.

FIGS. 2 and 3 illustrate a perspective view and a cross-sectional view, respectively, of complementary transistors including a thin-film omega transistor and a Fin Field-Effect (FinFET) having parallel current-flowing directions in accordance with some embodiments.

FIGS. 4 and 5 illustrate a perspective view and a cross-sectional view, respectively, of complementary transistors including a thin-film omega transistor and a FinFET having perpendicular current-flowing directions in accordance with some embodiments.

FIGS. 6A, 6B, 7A, 7B, 8A, 8B, 9A and 9B illustrate the cross-sectional views of intermediate stages in the formation of a thin-film omega transistor without work-function layer in accordance with some embodiments.

FIGS. 10A, 10B, 11A, 11B, 12A, 12B, 13A, 13B, 14A, 14B, 15A, and 15B illustrate the cross-sectional views of intermediate stages in the formation of a thin-film omega transistor including a work-function layer in accordance with some embodiments.

FIGS. 16 and 17 illustrate a cross-sectional view and a top view, respectively of a thin-film omega transistor in accordance with some embodiments.

FIGS. 18A and 18B illustrate the cross-sectional view of a thin-film omega transistor comprising a high-carrier-concentration oxide semiconductor layer in source and drain regions in accordance with some embodiments.

FIG. 19 illustrates the cross-sectional view of some neighboring thin-film omega transistors having either connected or separate channel layers in accordance with some embodiments.

FIGS. 20A and 20B illustrate the top views of a FinFET and a thin-film omega transistor, respectively, in accordance with some embodiments.

FIG. 21 illustrates a circuit diagram of complementary transistors including a thin-film omega transistor and a FinFET in accordance with some embodiments.

FIG. 22 illustrates a process flow for forming a thin-film omega transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A thin-film omega transistor and complementary transistors including a thin-film omega transistor and a Fin Field-Effect (FinFET) are provided. The methods of forming the same are provided. In accordance with some embodiments of the present disclosure, the thin-film omega transistor includes a fin-shaped gate, a gate dielectric on the top surface and the sidewalls of the fin-shaped gate, an oxide semiconductor layer over the gate dielectric to act as a channel, and a source region and a drain region over and contacting the oxide semiconductor layer. With the fin structures being adopted, the thin-film omega transistor has a high current. In addition, the thin-film omega transistor may form complementary devices with FinFETs. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

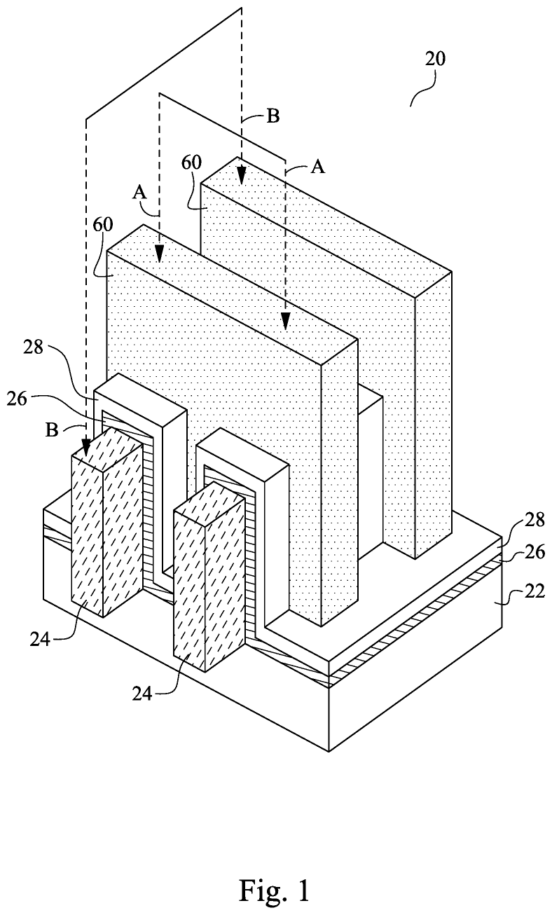

FIG. 1 illustrates a perspective of a thin-film omega transistor 20 in accordance with some embodiments. Thin-film omega transistor 20 may be formed over dielectric layer 22. The features underlying dielectric layer 22 are not shown. In accordance with some embodiments, the features underlying the dielectric layer 22 may include an etch stop layer, an inter-layer dielectric, a contact etch stop layer, a semiconductor substrate, and/or the like. Dielectric layer 22 may be a silicon oxide layer, a low-k dielectric layer, a high-k dielectric layer, or the like. For example, dielectric layer 22 may include an Inter-Metal Dielectric (IMD), in which metal lines and metal vias are formed.

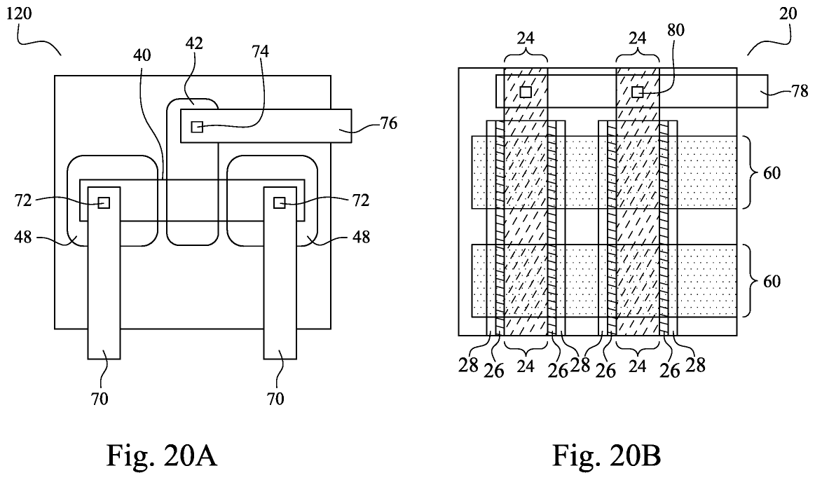

Gate fins 24 are formed on dielectric layer 22. In accordance with some embodiments, gate fins 24 are formed of a conductive material, which may be discussed in detail in subsequent paragraphs. FIG. 1 illustrates two gate fins 24, which may be electrically connected to each other, as shown in FIG. 20B. It is appreciated that thin-film omega transistor 20 may also be a single-gate-fin transistor, or may include more than two gate fins.

Gate dielectric 26 is formed on the sidewalls and the top surfaces of gate fins 24. Gate dielectric 26 is formed of a dielectric material, so that gate fins 24 are electrically insulated from the subsequently formed oxide semiconductor layer 28. In accordance with some embodiments, gate dielectric 26 comprises silicon oxide, silicon nitride, silicon oxynitride, a high-k dielectric material such as hafnium oxide, aluminum oxide, hafnium zirconium oxide (HfZrO₂), combinations thereof, multi-layers thereof, or the like. In accordance with some embodiments, gate dielectric 26 is formed through deposition, and hence includes horizontal portions extending on the top surface of dielectric layer 22. In accordance with alternative embodiments, gate dielectric 26 is formed through an oxidation process, in which a surface layer of each of gate fins 24 are oxidized to form the gate dielectric 26. The corresponding gate dielectric 26 does not include horizontal portions extending on the top surface of dielectric layer 22.

Oxide semiconductor layer 28 is formed on gate dielectric 26. Oxide semiconductor layer 28 comprises an oxide, and includes two sidewall portions on the sidewall portions of gate dielectric 26, and top portions over the top surface portions of gate dielectric 26. Accordingly, oxide semiconductor layer 28 has an omega shape, and the resulting transistor is referred to as a thin-film omega transistor. Gate fins 24, gate dielectric 26, and oxide semiconductor layers 28 collectively form fin structures protruding higher than dielectric layer 22.

In accordance with some embodiments, the oxide semiconductor layer 28 is for forming an n-type transistor, which is turned on when a positive bias voltage is applied on gate fins 24 (relative to the voltage on the respective source region). The respective oxide semiconductor layer 28 may include indium (In). Since indium has 5s electron orbit, the resulting oxide is conductive. By mixing indium with other elements such as gallium, (Ga), zinc (Zn), tungsten (W), and/or the like, the conductivity of the resulting oxide may be adjusted to have semiconductor characteristic. In accordance with some embodiments when the resulting transistor is an n-type transistor, oxide semiconductor layer 28 may be formed of or comprise Indium Tin Oxide (ITO), Indium Oxide (InO), Indium Gallium Zinc Oxide (IGZO), Indium Zinc Oxide (IZO), Indium Tungsten Oxide (IWO), or the like, or combinations thereof,

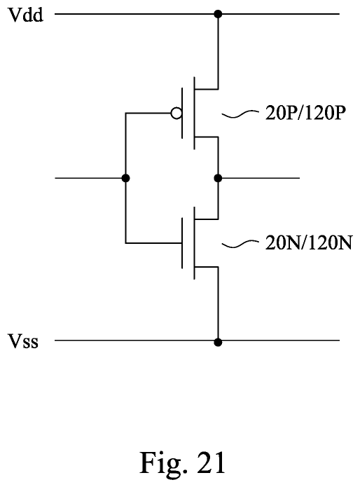

In accordance with alternative embodiments, the oxide semiconductor layer 28 is for forming a p-type transistor, which is turned on when a negative bias voltage is applied on the gate (relative to the voltage on the respective source region). The respective oxide semiconductor layer 28 may also include an oxide such as NiO, CuO, Cr₂O₃, Co₃O₄, Mn₃O₄, or the like. The example n-type transistor and p-type transistor are shown as transistor 20N and 20P (FIG. 21), respectively, which may form parts of an inverter in accordance with some embodiments.

Thin-film omega transistor 20 further includes source/drain regions 60. Throughout the description, source/drain region(s) may refer to a source or a drain, individually or collectively dependent upon the context. Source/drain regions 60 may be in physical contact with oxide semiconductor layer 28, with no silicide layer in between. In accordance with some embodiments, source/drain regions 60 are formed of or comprise Ti, TiN, W, Al, Mo, Ni, or the like, or alloys thereof.

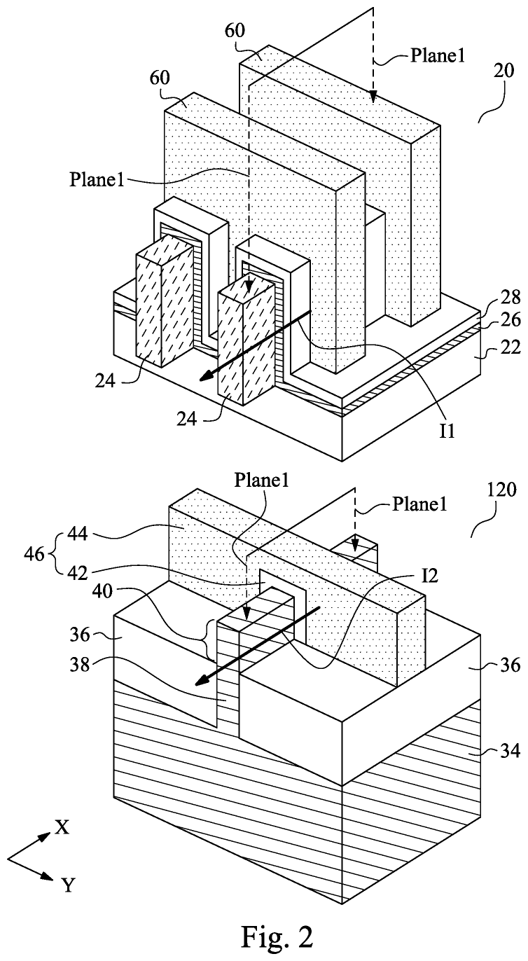

FIG. 2 illustrates a perspective view of transistors including a thin-film omega transistor 20 and a FinFET 120. In accordance with some embodiments, any one of thin-film omega transistor 20 and FinFET 120 may be an n-type transistor, and the other one may be a p-type transistor. Accordingly, thin-film omega transistor 20 and FinFET 120 may collectively form complementary transistors. In accordance with alternative embodiments, both of thin-film omega transistor 20 and FinFET 120 are p-type transistors or n-type transistors.

In accordance with some embodiments, FinFET 120 is formed based on semiconductor substrate 34. Shallow Trench Isolation (STI) regions 36 may be formed over a bulk portion of semiconductor substrate 34, with a semiconductor strip 38 being between STI regions 36. The top portion of semiconductor strip 38 may protrude higher than the top surfaces of STI regions 36 to form protruding semiconductor fin 40. Gate stack 46, which includes gate dielectric 42 and gate electrode 44, is formed on protruding semiconductor fin 40. The portions of protruding semiconductor fin 40 on the opposite sides of gate stack 46 may be replaced with an n-type semiconductor material to form the source/drain regions of an n-type transistor, or replaced with a p-type semiconductor material to form the source/drain regions of a p-type transistor. In accordance with some embodiments, FinFET 120 is formed using a front-end-of-line process. The formation of FinFET 120 may involve high temperatures, which may be higher than about 700° C.

Thin-film omega transistor 20 is formed over FinFET 120. In accordance with some embodiments, thin-film omega transistor 20 overlaps at least a part, or an entirety of, FinFET 120. This may reduce the routing distance between thin-film omega transistor 20 and FinFET 120 when they are electrically interconnected.

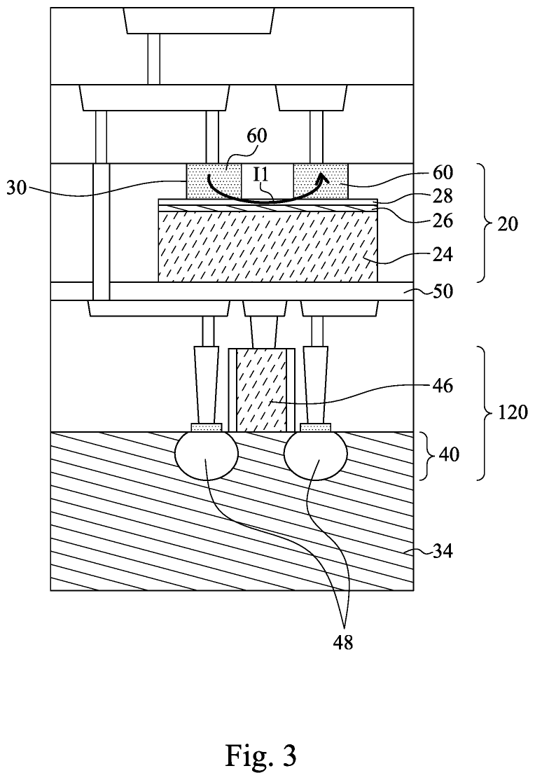

FIG. 3 illustrates a schematic cross-sectional view of thin-film omega transistor 20 and FinFET 120 in accordance with some embodiments. The cross-sectional view of thin-film omega transistor 20 is obtained from the plane Plane1-plane1 in FIG. 2. Accordingly, the source/drain regions 48 and the gate stack 46 of FinFET 120 are in the illustrated plane. Gate fin 24, gate dielectric 26, oxide semiconductor 28, and source/drain regions 60 of thin-film omega transistor 20 are also in the illustrated plane.

In accordance with some embodiments, the operation of thin-film omega transistor 20 is similar to the operation of FinFET 120. For example, when a positive voltage VGS is applied between gate fin 24 and the source region 60 of an n-type thin-film omega transistor 20, a conductive channel in oxide semiconductor layer 28 is turned on to electrically connect source region 60 to the corresponding drain region 60. Accordingly, current I1 flows between drain region 60 and source region 60. Conversely, when a voltage VGS lower than the threshold voltage of the n-type thin-film omega transistor 20 is applied between gate fin 24 and the source region 60, the channel in oxide semiconductor layer 28 is turned off to electrically disconnect source region 60 from the corresponding drain region 60. Conversely, for a p-type thin-film omega transistor 20, a negative voltage VGS turns on the channel, while a small negative voltage, zero voltage, or a positive voltage VGS turns off the channel.

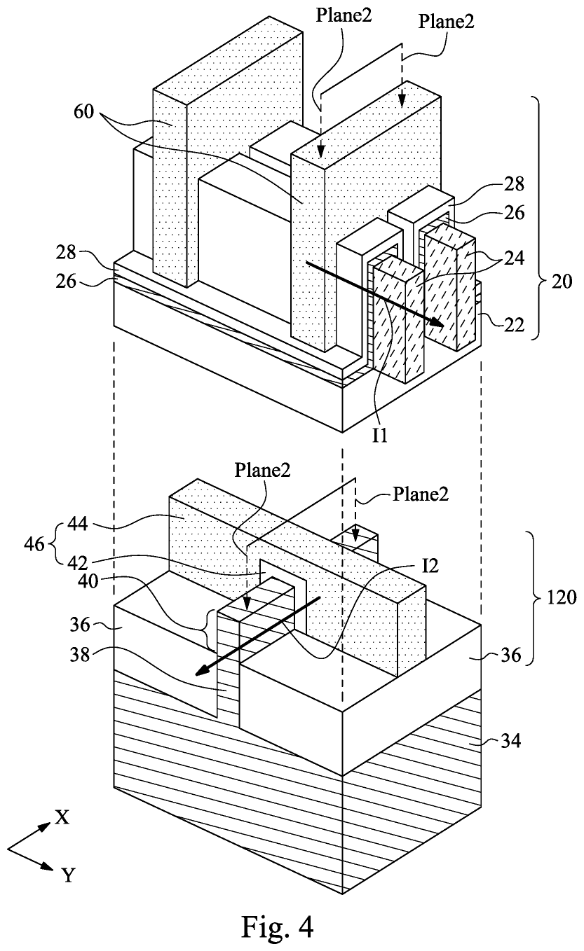

FIG. 4 illustrates a perspective view of transistors including a thin-film omega transistor 20 and a FinFET 120 in accordance with some embodiments. These embodiments are similar to the embodiments shown in FIGS. 2 and 3, except that in FIGS. 2 and 3, the current-flowing directions of thin-film omega transistor 20 and FinFET 120 are parallel to each other, while the current-flowing directions of thin-film omega transistor 20 and FinFET 120 in FIG. 4 are perpendicular to each other. For example, in FIG. 2, the current-flowing directions of the currents I1 and I2 of both of thin-film omega transistor 20 and FinFET 120, respectively are in the X direction, while in FIG. 4, the current-flowing direction of the current I1 of thin-film omega transistor 20 is in the Y direction, and the current-flowing direction of current I2 of FinFET 120 is in the X direction. By arranging the current-flowing directions of thin-film omega transistor 20 and FinFET 120 to be either perpendicular or parallel to each other, the metal routing of the metal lines and contact plugs may be optimized.

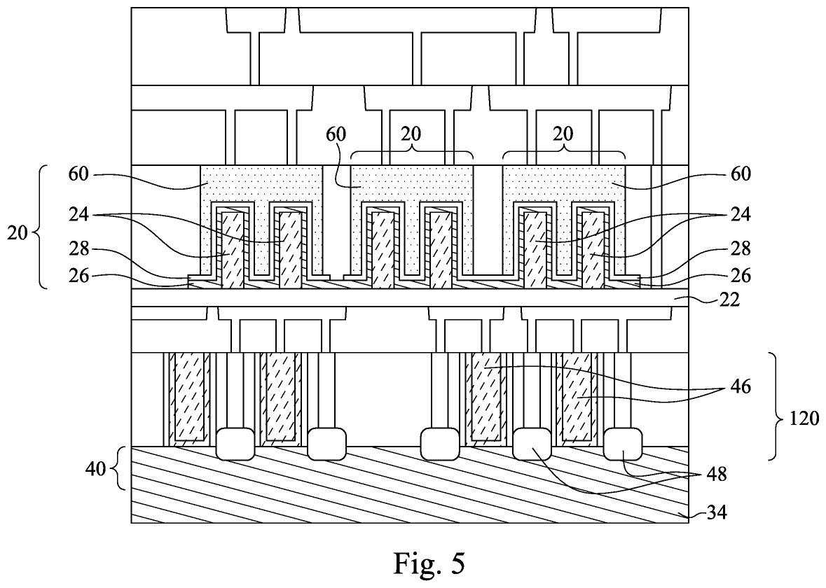

FIG. 5 illustrates a cross-sectional view of some thin-film omega transistors 20 and FinFETs 120 in accordance with some embodiments. The cross-sectional view of thin-film omega transistors 20 is obtained from the plane Plane2-Plane2 in FIG. 4. Accordingly, in FIG. 5, the source/drain regions 48 and gate stacks 46 of FinFET 120 are in the illustrated plane. The gate fin 24, gate dielectric 26, oxide semiconductor 28, and source/drain regions 60 of thin-film transistor 20 are in the illustrated plane.

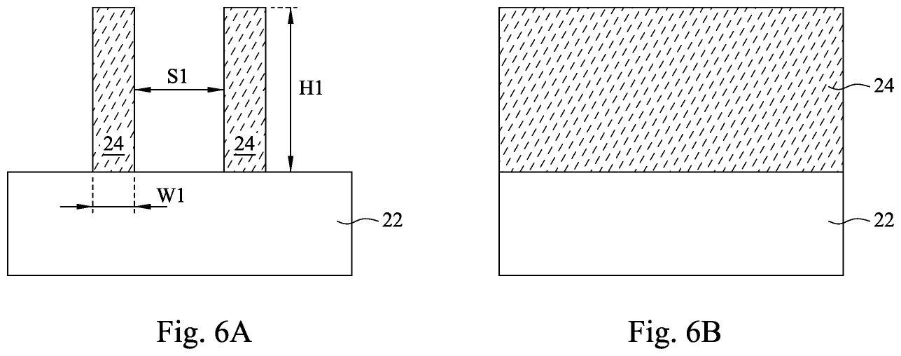

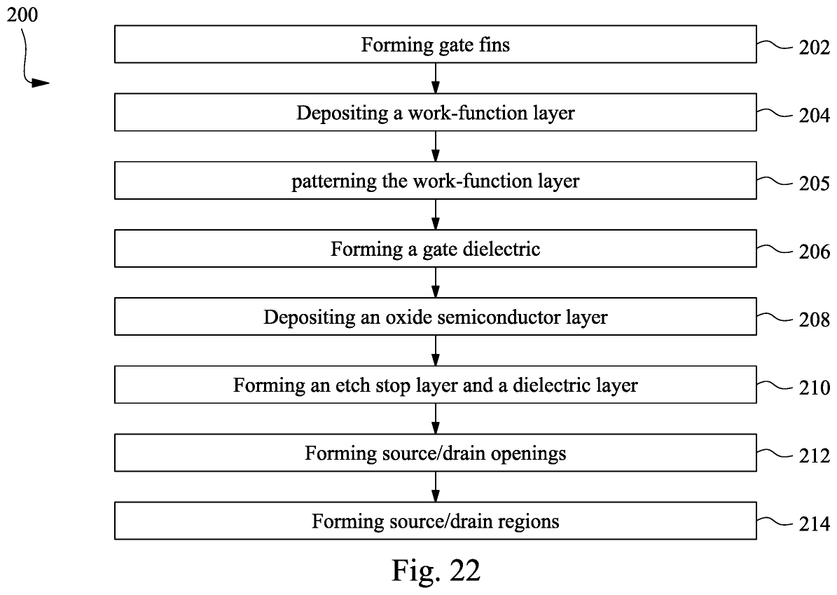

FIGS. 6A, 6B, 7A, 7B, 8A, 8B, 9A and 9B illustrate the cross-sectional views of intermediate stages in the formation of thin-film omega transistor 20 in accordance with some embodiments. The thin-film omega transistor 20 in accordance with these embodiments do not include work-function layer therein. The corresponding processes are also reflected schematically in the process flow 200 as shown in FIG. 22. FIGS. 6A, 7A, 8A, and 9A illustrate the cross-section A-A in FIG. 1, and FIGS. 6B, 7B, 8B, and 9B illustrate the cross-section B-B in FIG. 1. The formation of thin-film omega transistor 20 may be performed at temperatures lower than about 400° C. to preserve the properties of oxide semiconductor layers 28. This temperature range is compatible with back-end-of-line processes. Accordingly, thin-film omega transistor 20 may be formed in back-end-of-line structures, and are not formed in front-end-of-line structures.

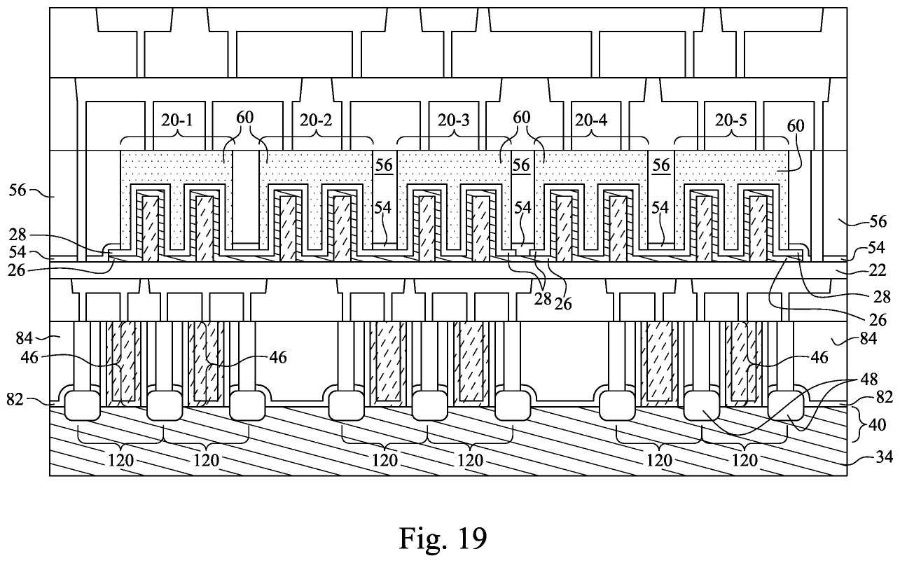

It is appreciated that the processes shown in FIGS. 6A, 6B, 7A, 7B, 8A, 8B, 9A and 9B are started after the processes for forming FinFET 120, and after the formation of dielectric layer 22. In accordance with some embodiments, the formation of FinFET 120 may include forming STI regions 36 (FIGS. 2 and 4) extending into semiconductor substrate 34. Referring to FIGS. 2 and 4, semiconductor strip 38 is between neighboring STI regions 36. STI regions 36 are then recessed. The top portion of semiconductor strip 38 thus protrudes higher than the top surfaces of the recessed STI regions 36 to form protruding semiconductor fin 40. A dummy gate stack is then formed on a portion of protruding semiconductor fin 40, followed by recessing some portions of the semiconductor strip 38, and forming source/drain regions starting from the respective recesses. Contact Etch Stop Layer 82 (CESL, FIG. 19) and Inter-Layer Dielectric (ILD) 84 are then formed. The dummy gate stack may then be replaced with replacement gate stacks 46, which may comprise a high-k gate dielectric and a metal gate stack.

After the formation of FinFET 120, some overlying features such as gate contact plugs, source/drain contact plugs, ILD(s), etch stop layer(s) may then be formed over FinFET 120. In accordance with some embodiments, the vertical space between thin-film omega transistor 20 and FinFET 120 may be filled with ILD(s), etch stop layer(s), and may or may not include IMDs, which may be low-k dielectric layers.

The process then turns to the process shown in FIGS. 6A and 6B, which illustrate the vertical cross-sections of a first plane A-A and a second plane B-B, respectively, in FIG. 1. The first vertical plane A-A is perpendicular to the lengthwise direction of gate fins 24. The second plane B-B is parallel to the lengthwise direction of gate fins 24.

Referring to FIG. 6A, gate fins 24 are formed. The respective process is illustrated as process 202 in the process flow 200 as shown in FIG. 22. The formation process may include depositing a blanket conductive layer, and then patterning the blanket conductive layer through etching. In accordance with some embodiment, gate fins 24 are formed of a conductive material, which may be formed of or comprise aluminum, aluminum copper, tungsten, cobalt, nickel, or the like, or alloys thereof. The blanket conductive layer may be deposited through Physical Vapor Deposition (PVD), Chemical Vapor Deposition (CVD), or the like.

In above-illustrated embodiments, gate fins 24 may be patterned by any suitable method. For example, the gate fins 24 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

The width W1 of gate fins 24 are selected to be not too big and not too small. If gate fins 24 are too wide, the usage of chip area is low, and the gate control of the fin will be poor. Conversely, if gate fins 24 are too narrow, gate fins 24 may collapse due to the significant height of gate fins 24. In accordance with some embodiments, the width W1 of gate fins 24 is in the range between about 5 nm and about 30 nm. The total count of gate fins 24 in a thin-film omega transistor may be in the range between 2 and 10 (while a single fin is also possible). It is realized that if a single gate fin 24 is adopted, there may be poor mobility. If too many gate fins 24 are adopted for one transistor, the chip area occupied by the corresponding device is too large. The height H1 of gate fins 24 may be in the range between about 20 nm and about 100 nm. The spacing S1 of gate fins 24 may be in the range between about 20 nm and about 120 nm.

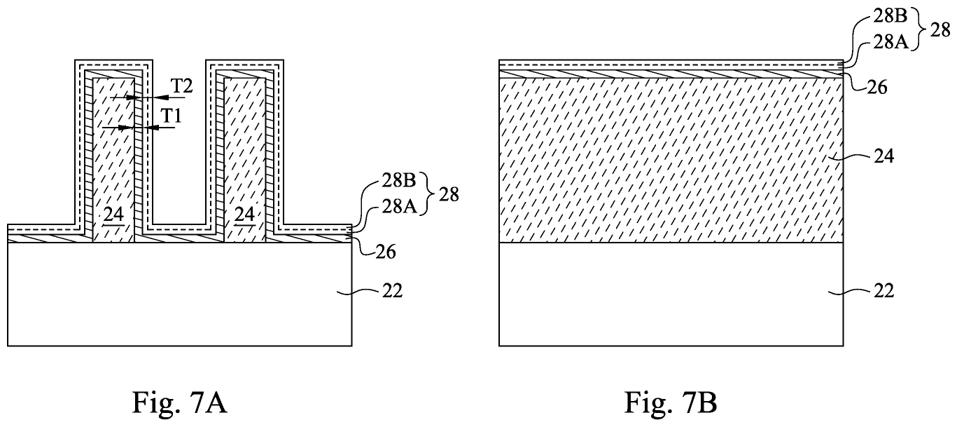

FIGS. 7A and 7B illustrate the formation of gate dielectric 26. The respective process is illustrated as process 206 in the process flow 200 as shown in FIG. 22. In accordance with some embodiments, gate dielectric 26 comprises silicon oxide, silicon nitride, silicon oxynitride, or the like. Gate dielectric 26 may also be formed of or comprises a high-k dielectric material such as hafnium oxide, aluminum oxide, hafnium zirconium oxide (HfZrO₂), combinations thereof, multi-layers thereof, or the like. In accordance with some embodiments, gate dielectric 26 is formed through deposition, and hence includes horizontal portions directly on the top surface of dielectric layer 22. In accordance with alternative embodiments, gate dielectric 26 is formed through oxidizing and/or nitriding the sidewall surface portions and the top surface portions of gate fins 24 to form metal oxide and/or nitride. Accordingly, gate dielectric 26 includes the oxide and/or the nitride of the metals used in gate fins 24. Furthermore, when formed through oxidation and/or nitridation, the corresponding gate dielectric 26 does not include horizontal portions over and contacting the top surface of dielectric layer 22. In accordance with some embodiments, the thickness T1 of gate dielectric 26 is in the range between about 1 nm and about 10 nm.

FIGS. 7A and 7B further illustrate the deposition of oxide semiconductor layer 28 in accordance with some embodiments. The respective process is illustrated as process 208 in the process flow 200 as shown in FIG. 22. The material of oxide semiconductor layer 28 has been discussed in preceding paragraphs, and hence is not repeated in detail therein. For example, oxide semiconductor layer 28 may comprise ITO, InO, IGZO, IZO, IWO, or the like, or combinations thereof when the resulting transistor is an n-type transistor. Oxide semiconductor layer 28 may comprise NiO, CuO, Cr₂O₃, Co₃O₄, Mn₃O₄, or the like when the resulting transistor is a p-type transistor.

Oxide semiconductor layer 28 may be formed through ALD, PVD, CVD, or the like. For example, when ALD is used to form IGZO, the precursor may include (3-dimethylaminopropyl)-dimethyl indium (DADI) as the indium precursor, diethylzinc (DEZ) as the zinc precursor, and trimethylgallium (TMGa) as the gallium precursor. O₂ plasma may be used for introducing oxygen. The wafer temperature during the deposition of oxide semiconductor layer 28 may be in the range between about 180° C. and about 250° C.

The thickness T2 of oxide semiconductor layer 28 is selected to be in certain range, and oxide semiconductor layer 28 is not to be too thick or too thin. When oxide semiconductor layer 28 is too thick, the carrier concentration in oxide semiconductor layer 28 is too high, and may cause the threshold voltage of the respective transistor to be too low (such as having zero threshold voltage or even negative threshold voltage), which means the transistor may be always turned on. When oxide semiconductor layer 28 is too thin, the carrier concentration is too high, and the threshold voltage is too high. In accordance with some embodiments, the thickness T2 of oxide semiconductor layer 28 is in the range between about 2 nm and about 15 nm.

In accordance with some embodiments, oxide semiconductor layer 28 comprises a homogeneous oxide semiconductor material, which may be selected from an aforementioned material. In accordance with alternative embodiments, oxide semiconductor layer 28 may be a composite layer include two or more sub-layers, which are formed of materials different from each other. For example, oxide semiconductor layer 28 may include a lower sub-layer 28A and an upper sub-layer 28B over lower sub-layer 28A. Upper sub-layer 28B may have a higher conductivity value than the lower sub-layer 28A. The interface between sub-layers 28A and 28B are illustrated as being dashed to indicate that oxide semiconductor layer 28 may be formed of a homogeneous material or may include sub-layers. Lower sub-layer 28A and upper sub-layer 28B may both be oxide semiconductor layers forming using materials selected from the above-recited candidate groups of materials. For example, lower sub-layer 28A and upper sub-layer 28B may both be the indium-containing semiconductor layers, with the upper sub-layer 28B having a higher indium atomic percentage than the lower sub-layer 28A.

In accordance with some embodiments, upper sub-layer 28B comprises a high-concentration oxide semiconductor material, which have a higher carrier concentration than lower sub-layer 28A. Accordingly, upper sub-layer 28B may have a higher conductivity value than lower sub-layer 28A. With upper sub-layer 28B having a higher carrier concentration, the contact resistance between source/drain regions 60 and oxide semiconductor layer 28 may be reduced. The type (p-type or n-type) of lower sub-layer 28A is the same as that of upper sub-layer 28B. For example, when upper sub-layer 28B is for forming an n-type transistor, and may comprise ITO, InO, IGZO, IZO, IWO, or the like, or combinations thereof, lower sub-layer 28A may also be selected from any of ITO, InO, IGZO, IZO, IWO, or the like. When upper sub-layer 28B is for forming a p-type transistor, and may comprise ITO, InO, IGZO, IZO, IWO, or the like, or combinations thereof, lower sub-layer 28A may also be selected from any of NiO, CuO, Cr₂O₃, Co₃O₄, Mn₃O₄, or the like.

Lower sub-layer 28A and upper sub-layer 28B may include same elements with different percentages of the elements. For example, lower sub-layer 28A and upper sub-layer 28B may both be one of ITO, InO, IGZO, IZO, IWO, with the indium atomic percentage IC28B in upper layer 28B being higher than the atomic percentage IC28A in lower layer 28A. For example, the ratio of IC28A/IC28B may be higher than about 1.2, and may be in the range between about 1.2 and 2.0. The formation process may include deposit lower sub-layer 28A, and increase the flow rate of the indium-containing gas to deposit upper sub-layer 28B. Alternatively, one of lower sub-layer 28A and the upper sub-layer 28B may comprise an element (such as tin, gallium, zirconium, nickel, Cu, Cr, Co, and/or Mn) that is not in the other one of lower sub-layer 28A and the upper sub-layer 28B.

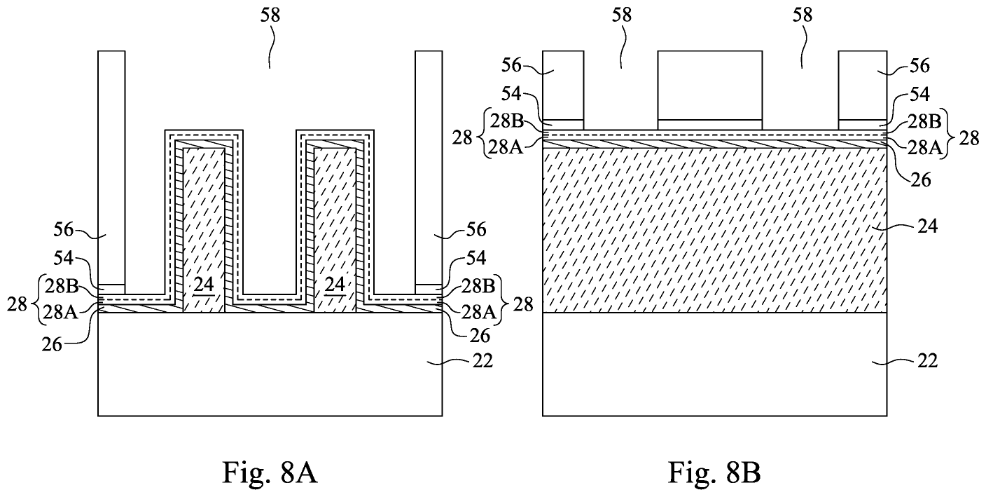

FIGS. 8A and 8B illustrate the formation of etch stop layer 54 and dielectric layer 56 in accordance with some embodiments. The respective process is illustrated as process 210 in the process flow 200 as shown in FIG. 22. Etch stop layer 54 may be formed of silicon oxide, silicon nitride, silicon carbo-nitride, or the like, and may be formed using CVD, ALD, or the like. Dielectric layer 56 may include a dielectric material formed using, for example, CVD, ALD, PECVD, FCVD, spin-on coating, or any other suitable deposition method. Dielectric layer 56 may be formed of or comprise silicon oxide, silicon nitride, silicon carbide, Phospho-Silicate Glass (PSG), Boro-Silicate Glass (BSG), Boron-Doped Phospho-Silicate Glass (BPSG), Undoped Silicate Glass (USG), or the like. Dielectric layer 56 may also be formed of or comprise a low-k dielectric material such as a carbon-containing dielectric material, which may have a dielectric constant (k value) lower than about 3.5, and possibly lower than about 3.0. The low-k dielectric material may be porous.

Next, source/drain openings 58 are formed by etching-through dielectric layer 56 and etch stop layer 54, with the etch stop layer 54 being used for stop etching of dielectric layer 56. The respective process is illustrated as process 212 in the process flow 200 as shown in FIG. 22. Oxide semiconductor layer 28 is thus formed.

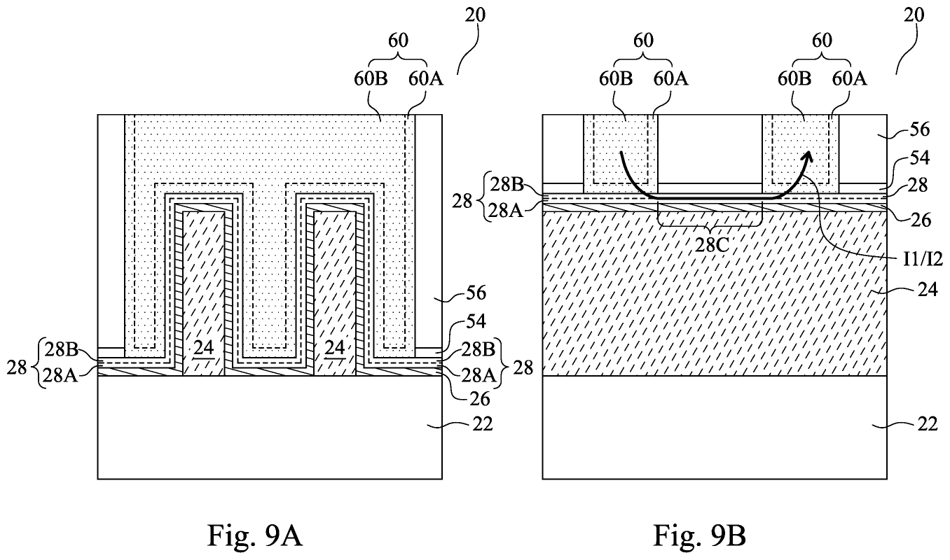

FIGS. 9A and 9B illustrate the formation of source/drain regions 60. The respective process is illustrated as process 214 in the process flow 200 as shown in FIG. 22. The formation process may include depositing a conductive material (such as a metallic material) into source/drain openings 58, and then performing a planarization process to remove excess conductive material. The deposition process may comprise ALD, CVD, PVD, or the like. The material of source/drain regions 60 may include a metallic material such as Ti, TiN, W, Al, Mo, Ni, or the like, or alloys thereof. Thin-film omega transistor 20 is thus formed.

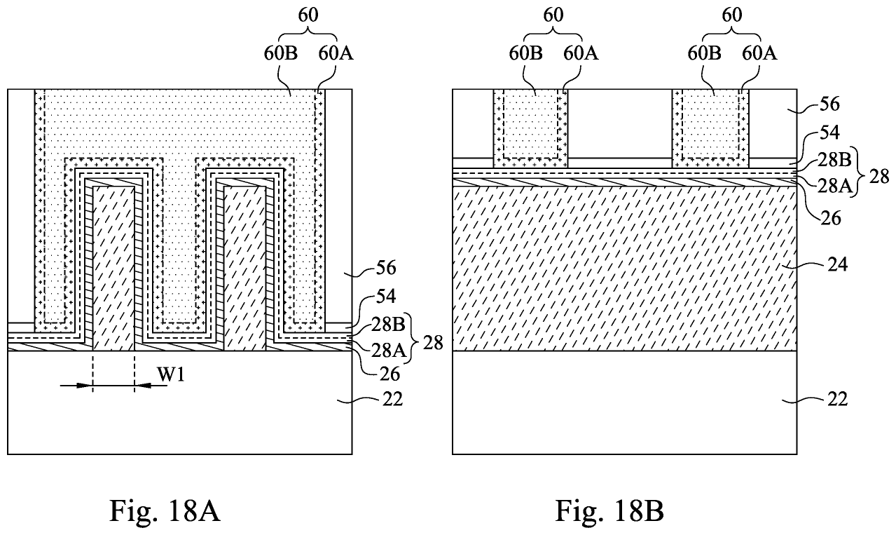

In accordance with some embodiments, source/drain regions 60 are formed of a homogeneous material, which may be the metallic material. In accordance with alternative embodiments, source/drain regions 60 are multi-layer regions including a plurality of sub-layers. For example, FIGS. 9A and 9B illustrate that source/drain regions 60 may include sub-layer 60A and sub-layer 60B on sub-layer 60A. The materials of sub-layers 60A and 60B are discussed in detail referring to FIGS. 18A and 18B. The interfaces between sub-layers 60A and 60B are illustrated as being dashed to indicate that source/drain regions 60 may be formed of a homogeneous material or may include sub-layers.

In the operation of thin-film omega transistor 20, when a proper bias voltage VGS (higher than the threshold voltage) is applied, a channel 28C (FIG. 9B) is formed in the oxide semiconductor layer 28 and between source/drain regions 60. Accordingly, thin-film omega transistor 20 is turned on, and current I1/I2 flows through the channel, wherein current I1 represents the current when thin-film omega transistor 20 is a n-type transistor and current I2 represents the current when thin-film omega transistor 20 is a p-type transistor. Otherwise, no channel is formed, and thin-film omega transistor 20 is turned off.

10A, 10B, 11A, 11B, 12A, 12B, 13A, 13B, 14A, 14B, 15A, and 15B illustrate the cross-sectional views of intermediate stages in the formation of a thin-film omega transistor 20 including a work-function layer in accordance with some embodiments. Unless specified otherwise, the materials and the formation processes of the components in these embodiments are essentially the same as the like components denoted by like reference numerals in the preceding embodiments. The details regarding the formation process and the materials of the components in these embodiments may thus be found in the discussion of the preceding embodiments. The processes are also shown in the process flow shown in FIG. 22, except that processes 204 and 205 are added.

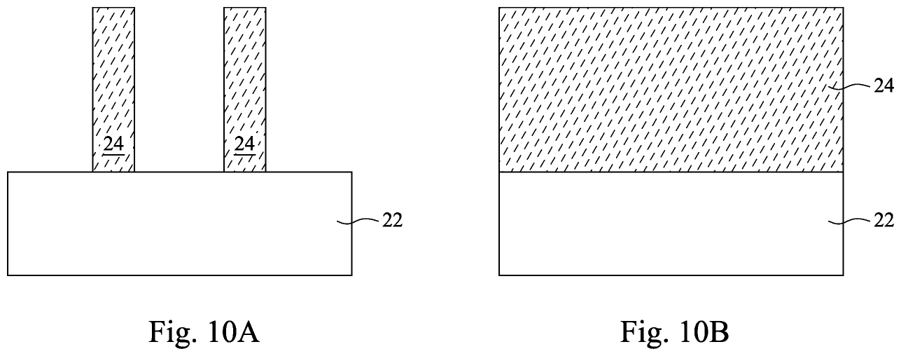

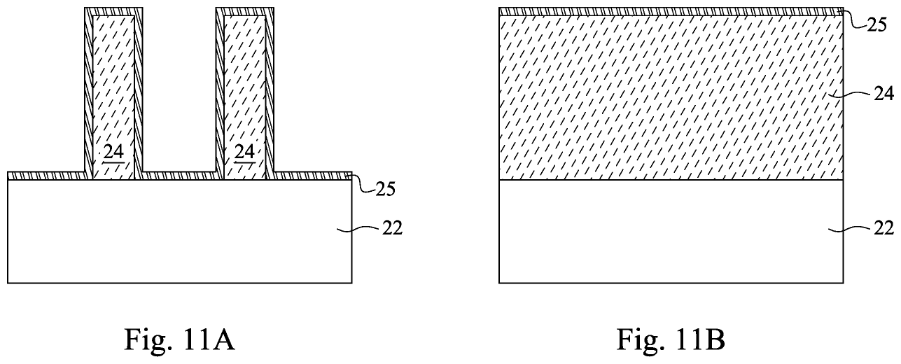

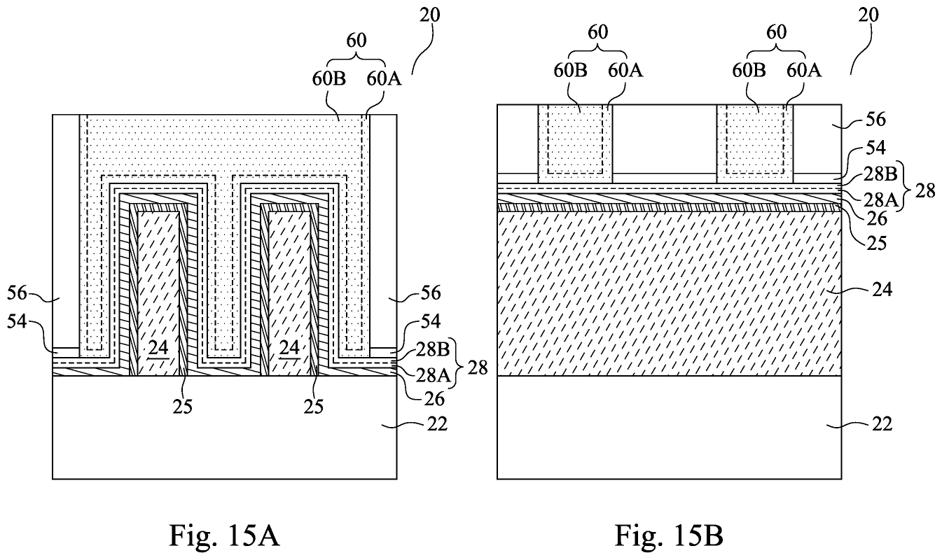

FIGS. 10A and 10B illustrate the formation of gate fins 24. Referring to FIGS. 11A and 11B, work-function layer 25 is deposited. The respective process is illustrated as process 204 in the process flow 200 as shown in FIG. 22. The work-function layer determines the work function of the corresponding gate, and includes at least one layer, or a plurality of layers formed of different materials. The material of the work-function layer 25 is selected according to whether the respective thin-film omega transistor is an n-type FinFET or a p-type FinFET. For example, when the resulting thin-film omega transistor 20 (FIGS. 15A and 15B) is a p-type transistor, the work-function layer 25 may be or may comprise TiN, W, Mo, or the like. When the resulting thin-film omega transistor (FIGS. 15A and 15B) is a p-type transistor, the work-function layer 25 may be or may comprise an aluminum-containing metal layer (such as TiAl, TiAlC, TiAlN, W, Mo, or the like). Work-function layer 25 may be formed through a conformal deposition process such as ALD, CVD, or the like.

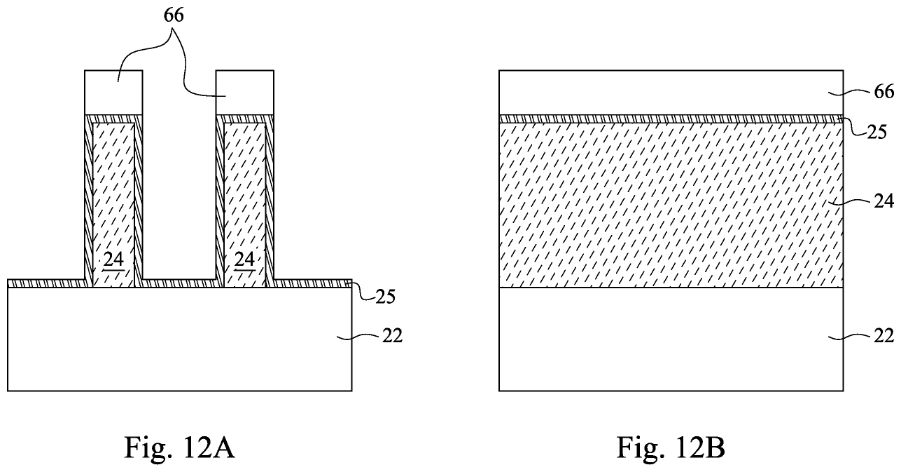

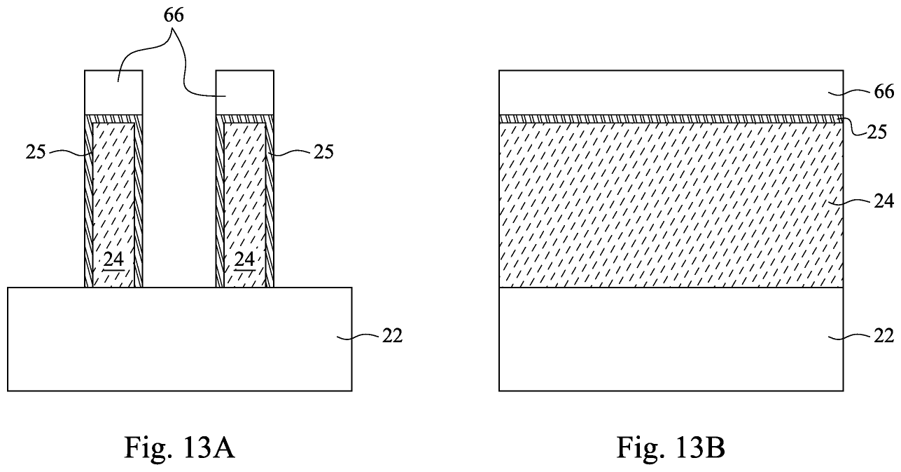

Referring to FIGS. 12A and 12B, etching mask 66 is formed and patterned. Etching mask 66 covers the portions of work-function layer 25 directly over gate fins 24, and leaves at least some portions of work-function layer 25 away from gate fins 24 exposed. Etching mask 66 may comprise a photoresist, and may be a single-layer etching mask, a dual-layer etching mask, a tri-layer etching mask, or the like. Next, work-function layer 25 is patterned, and the exposed portions of work-function layer 25 are removed through etching, as shown in FIGS. 13A and 13B. The respective process is illustrated as process 205 in the process flow 200 as shown in FIG. 22. Etching mask 66 is then removed.

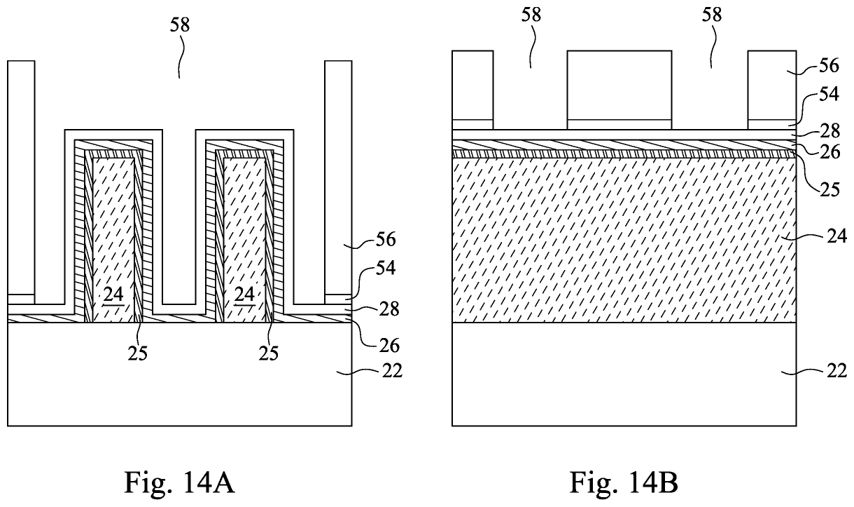

Referring to FIGS. 14A and 14B, gate dielectric 26 is formed. Oxide semiconductor layer 28 is then formed on gate dielectric 26. Next, as also shown in FIGS. 14A and 14B, etch stop layer 54 and dielectric layer 56 are formed, followed by the formation of source/drain openings 58. FIGS. 15A and 15B illustrate the formation of source/drain regions 60. Thin-film omega transistor 20 is thus formed. The interfaces between sub-layers 60A and 60B are illustrated as being dashed to indicate that source/drain regions 60 may be formed of a homogeneous material or may include sub-layers. The interfaces between lower sub-layer 28A and upper sub-layer 28B of oxide semiconductor layer 28 are also illustrated as being dashed to indicate that oxide semiconductor layer 28 may or may not include sub-layers.

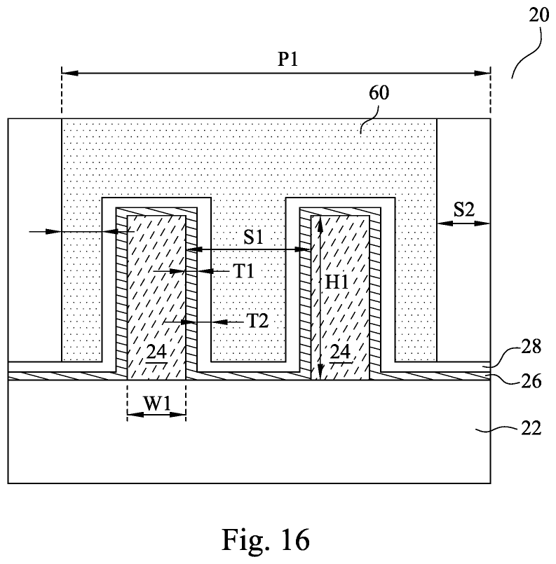

FIG. 16 illustrates a cross-sectional view of thin-film omega transistor 20 as shown in FIGS. 9A and 9B or in FIGS. 15A and 15B. The width W1, height H1, Spacing S1, and thicknesses T1 and T2 as discussed referring to previous figures are reproduced. Pitch P1 of thin-film omega transistor 20 and the neighboring nearest thin-film omega transistor 20 (not shown) may be in the range between about 60 nm and about 150 nm, assuming thin-film omega transistor 20 has two gate fins 24. Pitch P1 may also be the pitch of the source/drain region 60s of neighboring thin-film omega transistor 20. The spacing S2 between the illustrated source/drain region 60 and its nearest neighboring source/drain region 60 (not shown) may be in the range between about 10 nm and about 30 nm.

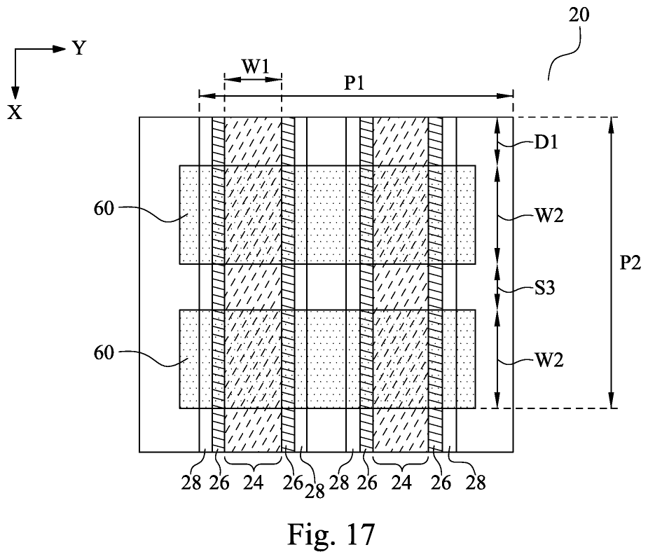

FIG. 17 illustrates a top view of thin-film omega transistor 20 as shown in FIGS. 9A and 9B or in FIGS. 15A and 15B in accordance with some embodiments. The width W2 of source/drain regions 60 may be in the range between about 40 nm and about 60 nm. The spacing S3 between neighboring source/drain regions 60 may be in the range between about 15 nm and about 45 nm. Gate fins 24 may extend (in the lengthwise direction) beyond the edges of source/drain regions 60 by distance D1, which may be in the range between about 15 nm and about 40 nm. The pitch P2 of the illustrated source/drain regions from the source/drain regions of the neighboring thin-film omega transistor 20 (not shown) may be in the range between about 70 nm and about 120 nm.

FIGS. 18A and 18B illustrate some embodiments when source/drain regions 60 include sub-layers 60A and 60B formed of different materials. In accordance with some embodiments, sub-layer 60A comprises a high-carrier-concentration oxide semiconductor material, which have higher carrier concentration than oxide semiconductor layer 28. With sub-layer 60A being formed of an oxide semiconductor material having a higher carrier concentration, the contact resistance between source/drain regions 60 and oxide semiconductor layer 28 may be reduced. The conductivity type (p-type or n-type) of sub-layer 60A is the same as that of oxide semiconductor layer 28. For example, when oxide semiconductor layer 28 is for forming an n-type transistor, and may comprise ITO, InO, IGZO, IZO, IWO, or the like, or combinations thereof, sub-layer 60A may also be selected from any of ITO, InO, IGZO, IZO, IWO, or the like, and combinations thereof. When oxide semiconductor layer 28 is for forming a p-type transistor, and comprises NiO, CuO, Cr₂O₃, Co₃O₄, Mn₃O₄, or the like, or combinations thereof, sub-layer 60A may also be selected from any of NiO, CuO, Cr₂O₃, Co₃O₄, Mn₃O₄, or the like, and combinations thereof. In accordance with some embodiments, when both of oxide semiconductor layer 28 and sub-layer 60A are formed of materials selected from the group consisting of ITO, InO, IGZO, IZO, IWO, or combinations thereof, the indium atomic percentage IC60A of sub-layer 60A may be higher than the indium atomic percentage IC28 of oxide semiconductor layer 28. For example, the ratio of IC60A/IC28 may be higher than about 1.2, and may be in the range between about 1.2 and 2.0.

FIG. 19 illustrates the cross-sectional view of some thin-film omega transistors 20 (including 20-1, 20-2, 20-3, 20-4, and 20-5) and the respective underlying FinFETs 120 in accordance with some embodiments. Thin-film omega transistors 20 and FinFETs 120 may be interconnected (through metal lines and contact plugs) to form complementary devices such as inverters. Each of the thin-film omega transistors 20-1, 20-2, 20-3, 20-4, and 20-5 may have the structures as discussed in preceding embodiments. Thin-film omega transistors 20-1 and 20-2 may be signally and electrically interconnected or disconnected from each other. In accordance with some embodiments, the oxide semiconductor layer 28 of thin-film omega transistor 20-1 and the oxide semiconductor layer 28 of thin-film omega transistor 20-2 are portions of the same continuous oxide semiconductor layer, without break in between, although thin-film omega transistors 20-1 and 20-2 are discrete transistors, and may be electrically interconnected or disconnected. For example, although the same continuous oxide semiconductor layer 28 is used by both of thin-film omega transistors 20-1 and 20-2, thin-film omega transistors 20-1 and 20-2 may have their gates electrically disconnected from each other, their source regions electrically disconnected from each other, and their drain regions electrically disconnected from each other. It is realized that having the same continuous oxide semiconductor layer used by both of thin-film omega transistors 20-1 and 20-2 may result in a slightly higher leakage current, which may be acceptable in some applications.

FIG. 19 also illustrates thin-film omega transistors 20-3 and 20-4 in accordance with alternative embodiments. In these embodiments, the oxide semiconductor layer 28 of thin-film omega transistor 20-3 and the oxide semiconductor layer 28 of thin-film omega transistor 20-4 are physically separated from each other, with a break physically and electrically separating the oxide semiconductor layers 28 from each other. The break may be fully or partially filled with etch stop layer 54, and may or may not be filled with dielectric layer 56. The break may be formed by a patterning process through etching, which may use the underlying gate dielectric 26 as an etch stop layer.

FIGS. 20A and 20B illustrate the top views of FinFET 120 and thin-film omega transistor 20, respectively in accordance with some embodiments. As shown in FIG. 20A, FinFET 120 includes source/drain regions 48, which are connected to the opposite ends of protruding semiconductor fin 40. Gate stack 42 crosses over protruding semiconductor fin 40. Source/drain regions 48 are electrically connected to metal lines 70 through source/drain contact plugs 72. Gate stack 42 is electrically connected to metal line 76 through gate contact plugs 74.

As shown in FIG. 20B, thin-film omega transistor 20 includes gate fins 24, gate dielectrics 26, and oxide semiconductor layers 28, with source/drain regions 60 crossing over oxide semiconductor layer 28. Gate fins 24 are electrically connected to metal line 78 through gate contact plugs 80.

FIG. 21 illustrates a circuit diagram of an example circuit formed of complementary transistors including an n-type transistor and a p-type transistor. The illustrated circuit may be an inverter in accordance with an example embodiment. The n-type transistor may be an n-type thin-film transistor 20N or an n-type FinFET 120N. The p-type transistor may be a p-type thin-film transistor 20P or a p-type FinFET 120P.

The embodiments of the present disclosure have some advantageous features. By forming thin-film omega transistors having omega-shaped channel regions, the chip areas occupied by the corresponding transistors is increased, while the saturation currents of the transistors can still be increased. Thin-film omega transistors may be formed directly over front-end-of-line transistors such as FinFETs, so that the chip areas are further saved.

In accordance with some embodiments of the present disclosure, a method comprises forming a first thin-film omega transistor comprising forming a gate fin over a first dielectric layer; forming a first gate dielectric on sidewalls and a top surface of the gate fin; depositing a first oxide semiconductor layer over the first gate dielectric, wherein the gate fin, the first gate dielectric, and the first oxide semiconductor layer collectively form a fin structure; forming a source region contacting first sidewalls and a first top surface of a first portion of the first oxide semiconductor layer; and forming a drain region contacting second sidewalls and a second top surface of a second portion of the first oxide semiconductor layer.

In an embodiment, the method further comprises forming a FinFET on a semiconductor substrate, wherein the first dielectric layer is overlying the semiconductor substrate and the FinFET. In an embodiment, the first thin-film omega transistor overlaps the FinFET. In an embodiment, the first thin-film omega transistor and the FinFET are of opposite conductivity types, and the method further comprises electrically interconnecting the first thin-film omega transistor and the FinFET to form a complementary device. In an embodiment, each of the source region and the drain region comprises an additional oxide semiconductor layer; and a metallic layer on the additional oxide semiconductor layer. In an embodiment, the forming the source region and the drain region comprises forming a second dielectric layer on the fin structure; forming a source opening and a drain opening exposing the first portion and the second portion, respectively, of the first oxide semiconductor layer; depositing the additional oxide semiconductor layer extending into the source opening and the drain opening; and depositing the metallic layer on the additional oxide semiconductor layer.

In an embodiment, the additional oxide semiconductor layer has a higher conductivity value than the first oxide semiconductor layer. In an embodiment, both of the first oxide semiconductor layer and the additional oxide semiconductor layer comprise indium oxide, and wherein the additional oxide semiconductor layer has a higher indium atomic percentage than the first oxide semiconductor layer. In an embodiment, the method further comprises forming a second thin-film omega transistor immediately neighboring the first thin-film omega transistor, wherein the second thin-film omega transistor comprises a second gate dielectric and a second oxide semiconductor layer on the second gate dielectric, wherein the first thin-film omega transistor and the second thin-film omega transistor are discrete transistors electrically and signally disconnected from each other, and wherein the first oxide semiconductor layer and the second oxide semiconductor layer are portions of a continuous oxide semiconductor layer.

In an embodiment, the method further comprises forming a second thin-film omega transistor immediately neighboring the first thin-film omega transistor, wherein the second thin-film omega transistor comprises a second gate dielectric and a second oxide semiconductor layer, wherein the first thin-film omega transistor and the second thin-film omega transistor are discrete transistors electrically and signally disconnected from each other, and wherein the first oxide semiconductor layer and the second oxide semiconductor layer are separated from each other by an etch stop layer and an additional dielectric layer. In an embodiment, the first gate dielectric and the second gate dielectric are portions of a continuous dielectric layer.

In accordance with some embodiments of the present disclosure, a structure comprises a first dielectric layer; and a thin-film omega transistor comprising a gate fin over the first dielectric layer; a gate dielectric on sidewalls and a top surface of the gate fin; an oxide semiconductor layer over the gate dielectric; a source region contacting first sidewalls and a first top surface of a first portion of the oxide semiconductor layer; and a drain region contacting second sidewalls and a second top surface of a second portion of the oxide semiconductor layer; an etch stop layer over and contacting the oxide semiconductor layer; and a second dielectric layer over the etch stop layer, wherein the source region and the drain region are in the etch stop layer and the second dielectric layer. In an embodiment, the structure further comprises a FinFET on a semiconductor substrate, wherein the first dielectric layer is over the semiconductor substrate and FinFET, and wherein the thin-film omega transistor overlaps the FinFET.

In an embodiment, the thin-film omega transistor and the FinFET are of opposite conductivity types, and the structure further comprises metal lines and contact plugs electrically interconnecting the thin-film omega transistor and the FinFET to form a complementary device. In an embodiment, each of the source region and the drain region comprises an additional oxide semiconductor layer having a U-shaped cross-sectional-view shape; and a metallic layer between opposite sidewall portions of the additional oxide semiconductor layer. In an embodiment, the additional oxide semiconductor layer has a higher conductivity value than the oxide semiconductor layer. In an embodiment, both of the oxide semiconductor layer and the additional oxide semiconductor layer comprise indium oxide, and wherein the additional oxide semiconductor layer has a higher indium atomic percentage than the oxide semiconductor layer.

In accordance with some embodiments of the present disclosure, a structure comprises a first dielectric layer; a thin-film omega transistor comprising a conductive fin protruding higher than a top surface of the first dielectric layer; a gate dielectric on the conductive fin; an oxide semiconductor layer on the gate dielectric, wherein the oxide semiconductor layer has a substantially omega-shaped cross-sectional-view shape; a source region contacting a first portion of the oxide semiconductor layer; and a drain region contacting a second portion of the oxide semiconductor layer; and a dielectric layer over and contacting a third portion of the oxide semiconductor layer, wherein the third portion is between, and interconnects, the first portion and the second portion.

In an embodiment, the source region comprises an additional oxide semiconductor layer comprising a bottom portion over and contacting the oxide semiconductor layer; and sidewall portions over, and connecting to opposite ends of, the bottom portion; and a metallic region over the bottom portion and between the sidewall portions. In an embodiment, the oxide semiconductor layer comprises a first sub-layer having a first conductivity value; and a second sub-layer over the first sub-layer, wherein the second sub-layer has a second conductivity value higher than the first conductivity value.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first thin-film omega transistor comprising:
forming a gate fin over a first dielectric layer;
forming a first gate dielectric on sidewalls and a top surface of the gate fin;
depositing a first oxide semiconductor layer over the first gate dielectric, wherein the gate fin, the first gate dielectric, and the first oxide semiconductor layer collectively form a fin structure;
forming a source region contacting first sidewalls and a first top surface of a first portion of the first oxide semiconductor layer; and
forming a drain region contacting second sidewalls and a second top surface of a second portion of the first oxide semiconductor layer.

2. The method of claim 1 further comprising forming a Fin Field-Effect Transistor (FinFET) on a semiconductor substrate, wherein the first dielectric layer is overlying the semiconductor substrate and the FinFET.

3. The method of claim 2, wherein the first thin-film omega transistor overlaps the FinFET.

4. The method of claim 2, wherein the first thin-film omega transistor and the FinFET are of opposite conductivity types, and the method further comprises:
electrically interconnecting the first thin-film omega transistor and the FinFET to form a complementary device.

5. The method of claim 1, wherein each of the source region and the drain region comprises:
an additional oxide semiconductor layer; and
a metallic layer on the additional oxide semiconductor layer.

6. The method of claim 5, wherein the forming the source region and the drain region comprises:
forming a second dielectric layer on the fin structure;
forming a source opening and a drain opening exposing the first portion and the second portion, respectively, of the first oxide semiconductor layer;
depositing the additional oxide semiconductor layer extending into the source opening and the drain opening; and
depositing the metallic layer on the additional oxide semiconductor layer.

7. The method of claim 5, wherein the additional oxide semiconductor layer has a higher conductivity value than the first oxide semiconductor layer.

8. The method of claim 5, wherein both of the first oxide semiconductor layer and the additional oxide semiconductor layer comprise indium oxide, and wherein the additional oxide semiconductor layer has a higher indium atomic percentage than the first oxide semiconductor layer.

9. The method of claim 1 further comprising:
forming a second thin-film omega transistor immediately neighboring the first thin-film omega transistor, wherein the second thin-film omega transistor comprises a second gate dielectric and a second oxide semiconductor layer on the second gate dielectric, wherein the first thin-film omega transistor and the second thin-film omega transistor are discrete transistors electrically and signally disconnected from each other, and wherein the first oxide semiconductor layer and the second oxide semiconductor layer are portions of a continuous oxide semiconductor layer.

10. The method of claim 1 further comprising:
forming a second thin-film omega transistor immediately neighboring the first thin-film omega transistor, wherein the second thin-film omega transistor comprises a second gate dielectric and a second oxide semiconductor layer, wherein the first thin-film omega transistor and the second thin-film omega transistor are discrete transistors electrically and signally disconnected from each other, and wherein the first oxide semiconductor layer and the second oxide semiconductor layer are separated from each other by an etch stop layer and an additional dielectric layer.

11. The method of claim 10, wherein the first gate dielectric and the second gate dielectric are portions of a continuous dielectric layer.

12. A structure comprising:
a first dielectric layer; and
a thin-film omega transistor comprising:
a gate fin over the first dielectric layer;
a gate dielectric on sidewalls and a top surface of the gate fin;
an oxide semiconductor layer over the gate dielectric;
a source region contacting first sidewalls and a first top surface of a first portion of the oxide semiconductor layer; and
a drain region contacting second sidewalls and a second top surface of a second portion of the oxide semiconductor layer;
an etch stop layer over and contacting the oxide semiconductor layer; and
a second dielectric layer over the etch stop layer, wherein the source region and the drain region are in the etch stop layer and the second dielectric layer.

13. The structure of claim 12 further comprising:
a Fin Field-Effect Transistor (FinFET) on a semiconductor substrate, wherein the first dielectric layer is over the semiconductor substrate and FinFET, and wherein the thin-film omega transistor overlaps the FinFET.

14. The structure of claim 13, wherein the thin-film omega transistor and the FinFET are of opposite conductivity types, and the structure further comprises:
metal lines and contact plugs electrically interconnecting the thin-film omega transistor and the FinFET to form a complementary device.

15. The structure of claim 12, wherein each of the source region and the drain region comprises:
an additional oxide semiconductor layer having a U-shaped cross-sectional-view shape; and
a metallic layer between opposite sidewall portions of the additional oxide semiconductor layer.

16. The structure of claim 15, wherein the additional oxide semiconductor layer has a higher conductivity value than the oxide semiconductor layer.

17. The structure of claim 15, wherein both of the oxide semiconductor layer and the additional oxide semiconductor layer comprise indium oxide, and wherein the additional oxide semiconductor layer has a higher indium atomic percentage than the oxide semiconductor layer.

18. A structure comprising:
a first dielectric layer;
a thin-film omega transistor comprising:
a conductive fin protruding higher than a top surface of the first dielectric layer;
a gate dielectric on the conductive fin;
an oxide semiconductor layer on the gate dielectric, wherein the oxide semiconductor layer has a substantially omega-shaped cross-sectional-view shape;
a source region contacting a first portion of the oxide semiconductor layer; and
a drain region contacting a second portion of the oxide semiconductor layer; and
a dielectric layer over and contacting a third portion of the oxide semiconductor layer, wherein the third portion is between, and interconnects, the first portion and the second portion.

19. The structure of claim 18, wherein the source region comprises:
an additional oxide semiconductor layer comprising:
a bottom portion over and contacting the oxide semiconductor layer; and
sidewall portions over, and connecting to opposite ends of, the bottom portion; and
a metallic region over the bottom portion and between the sidewall portions.

20. The structure of claim 18, wherein the oxide semiconductor layer comprises:
a first sub-layer having a first conductivity value; and
a second sub-layer over the first sub-layer, wherein the second sub-layer has a second conductivity value higher than the first conductivity value.
